(19) United States
(12) Patent Application Publication
(10) Pub. No.: US 2015/0179596 A1
(43) Pub. Date: Jun. 25, 2015

(54) SEMICONDUCTOR PACKAGE

(71) Applicant: SAMSUNG ELECTRO-MECHANICS CO., LTD., Suwon-Si (KR)

(72) Inventors: Won CHOI, Cheongju-si (KR); Young Hun KIM, Yeongi-gun (KR); Hyun Kyung PARK, Cheongju-si (KR)

(21) Appl. No.: 14/543,105

(22) Filed: Nov. 17, 2014

(30) Foreign Application Priority Data
Dec. 24, 2013 (KR) 10-2013-0162292

(51) Int. Cl. H01L 23/00

(52) U.S. Cl. CPC H01L 24/16; H01L 24/13; H01L 2224/13014; H01L 2224/13015; H01L 2224/11849; H01L 2224/13147; H01L 2924/01029

(57) ABSTRACT

Disclosed herein is a semiconductor package capable of stably implementing an interlayer bonding of a stacked board, the semiconductor package includes: a lower package having a chip module mounted thereon so as to be connected to a circuit pattern; an upper package stacked on the lower package and having an electrical device mounted thereon; and a bump receiving a tip of a solder ball electrically connecting the lower package and the upper package and coupled to the solder ball.

### CROSS REFERENCE(S) TO RELATED APPLICATIONS

This application claims the foreign priority benefit under 35 U.S.C. Section 119 of Korean Patent Application Serial No. 10-2013-0162292, entitled “Semiconductor Package” filed on Dec. 24, 2013, which is hereby incorporated by reference in its entirety into this application.

### BACKGROUND OF THE INVENTION

1. Technical Field

The present invention relates to a semiconductor package, and more particularly, to a semiconductor package capable of stably improving an interlayer bonding of a stacked board.

2. Description of the Related Art

In general, a printed circuit board (PCB), which serves to electrically connect or mechanically fix electronic components, includes an insulating layer formed of an insulating material such as a phenol resin, an epoxy resin, or the like, and a copper foil attached to the insulation layer to thereby form a predetermined wiring pattern.

The PCB is mainly classified into a single PCB in which the wiring pattern is formed on only one surface of the insulation layer, a double PCB in which the wiring pattern is formed on both surfaces of the insulation layer, and a multi layer PCB in which a plurality of insulation layers having the wiring pattern formed thereon are stacked to form the wiring pattern in a multi layer shape.

In this case, in the case in which the multi layer PCB has a structure a semiconductor device is mounted on each layer, a solder ball is interposed between the respective layers to electrically connect each layer to each other.

The solder ball is disposed between the PCB having an electrical device mounted thereon and a printed circuit board disposed at a lower portion thereof, and in the case in which another electrical device is disposed on the lower portion PCB, the solder ball is disposed at both sides of the electrical device.

However, in a semiconductor package according to the related art configured by the configuration as described above, the solder ball interposed between a top package and a lower package among a structure recently configured by a 3D package is not suitable for a standard of the solder ball connecting upper and lower printed circuit boards due to miniaturization of a circuit pattern configured on each layer and an expanded installation space of the semiconductor package, such that it is difficult to cope with a fine circuit pattern and therefore, interlayer match between the respective packages is not accurately performed.

### SUMMARY OF THE INVENTION

An object of the present invention is to provide a semiconductor package including a bump so that a solder ball interposed between upper and lower printed circuit boards may maintain a stable displacement state.

Another object of the present invention is to provide a bump having a hollow shape in which an inner portion is perforated or a concave shape in which an upper portion is depressed so as to maintain a stable coupling state with the solder ball.

According to an exemplary embodiment of the present invention, there is provided a semiconductor package including: a lower package having a chip module mounted thereon so as to be connected to a circuit pattern; an upper package stacked on the lower package and having an electrical device mounted thereon; and a bump receiving a tip of a solder ball electrically connecting the lower package and the upper package and coupled to the solder ball.

The bump may use copper which is the same material as the circuit pattern, as a material thereof.

The bump may have a receiving space formed therein and the receiving space of the bump may have an inner diameter smaller than a diameter of the solder ball.

The bump may have an upper surface configured so as to be depressed.

The bump may be configured so as to correspond to the positions and number of solder balls and the solder ball may be partially melted and introduced into a receiving space of the bump when a reflow process is performed.

The bump may be formed in any one shape of a circular shape, a quadrangle shape, and a polygonal shape and the bump may be configured so as to be protruded integrally with the circuit pattern of the lower package.

### BRIEF DESCRIPTION OF THE DRAWINGS

FIG. 1 is a view illustrating a semiconductor package according to an exemplary embodiment of the present invention;

FIG. 2A is a view illustrating a state in which a circuit pattern and a solder resist are applied onto a printed circuit board of a semiconductor package according to an exemplary embodiment of the present invention;

FIG. 2B is a view illustrating a state in which a seed layer is formed on a printed circuit board of a semiconductor package according to an exemplary embodiment of the present invention;

FIG. 2C is a view illustrating a state in which a dry film is exposed and developed on a printed circuit board of a semiconductor package according to an exemplary embodiment of the present invention;

FIG. 2D is a view illustrating a state in which a copper post is plated on a printed circuit board of a semiconductor package according to an exemplary embodiment of the present invention;

FIG. 2E is a view illustrating a state in which the dry film is delaminated from a printed circuit board of a semiconductor package according to an exemplary embodiment of the present invention;

FIG. 2F is a view illustrating a state in which an etching process is performed on a printed circuit board of a semiconductor package according to an exemplary embodiment of the present invention;

FIG. 3A is a view illustrating a state before an upper printed circuit board of a semiconductor package according to an exemplary embodiment of the present invention and a lower printed circuit board thereof are bonded;

FIG. 3B is a view illustrating a state in which the upper printed circuit board of the semiconductor package according to an exemplary embodiment of the present invention and the lower printed circuit board thereof are bonded;

FIG. 3C is a view illustrating a state in which a reflow is performed in a state in which the upper printed circuit board of the semiconductor package according to an exemplary embodiment of the present invention and the lower printed circuit board thereof are bonded; and

FIG. 3D is a view illustrating a state in which the reflow is completed in a state in which the upper printed circuit board of the semiconductor package according to an exemplary embodiment of the present invention and the lower printed circuit board thereof are bonded.

### DESCRIPTION OF THE PREFERRED EMBODIMENTS

Hereinafter, an exemplary embodiment of the present invention will be described in detail with reference to the accompanying drawings.

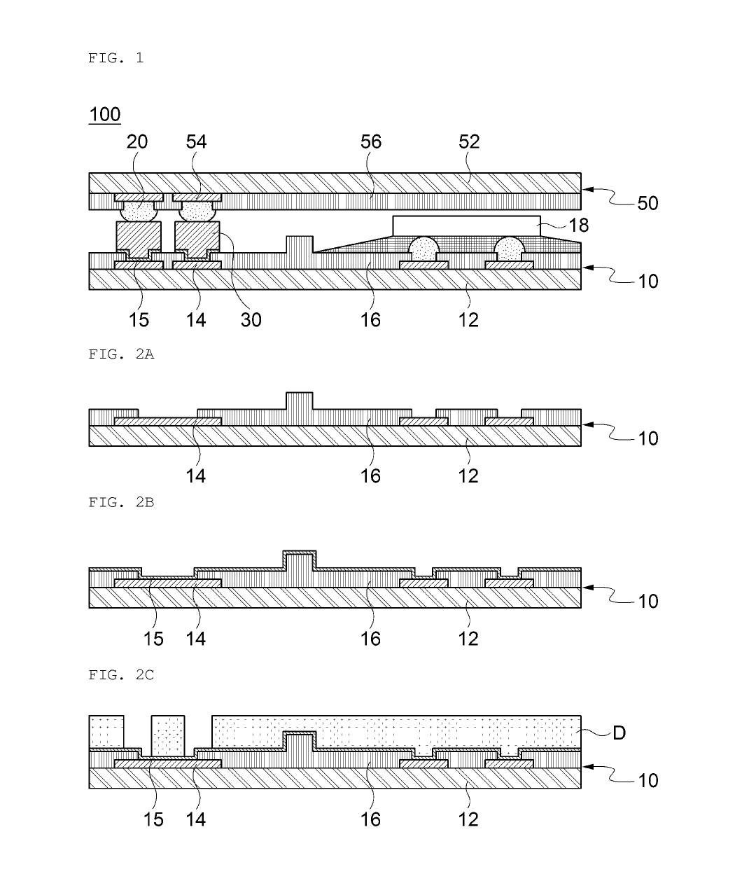

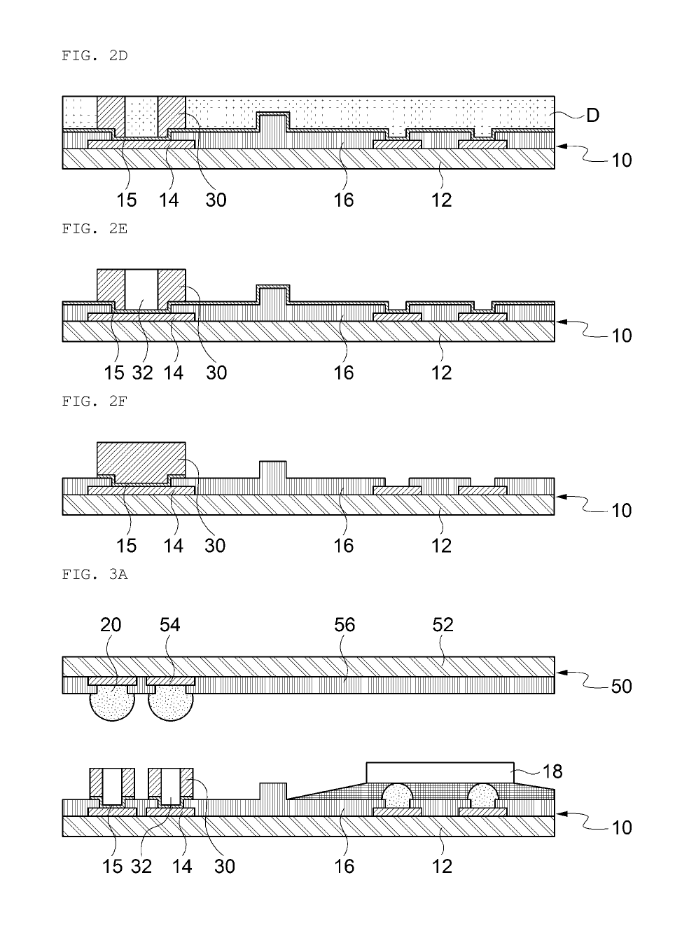

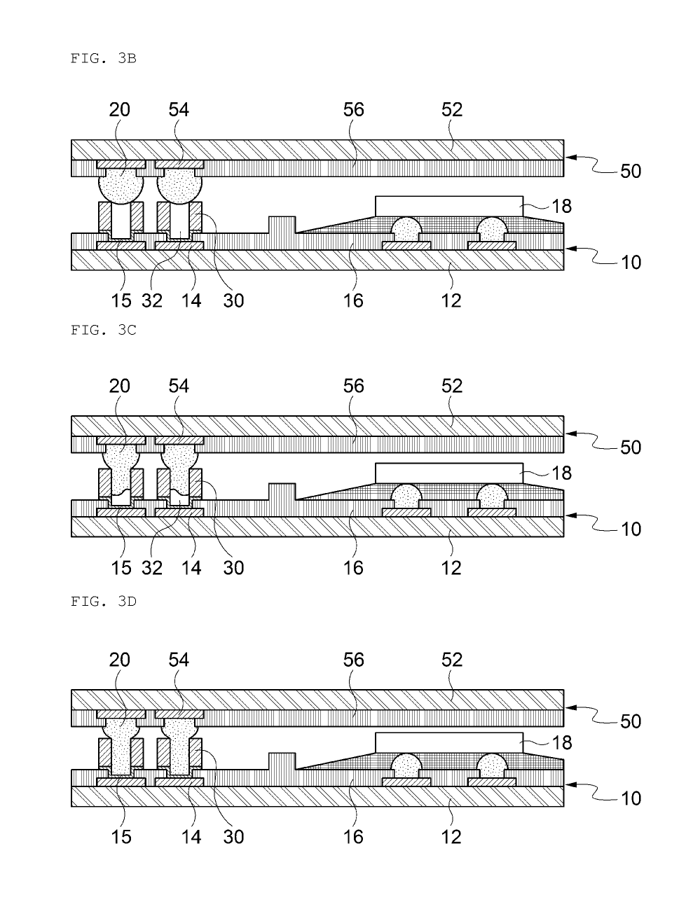

FIG. 1 is a view illustrating a semiconductor package according to an exemplary embodiment of the present invention, FIG. 2A is a view illustrating a state in which a circuit pattern and a solder resist are applied onto a printed circuit board of a semiconductor package according to an exemplary embodiment of the present invention, FIG. 2B is a view illustrating a state in which a seed layer is formed on a printed circuit board of a semiconductor package according to an exemplary embodiment of the present invention, FIG. 2C is a view illustrating a state in which a dry film is exposed and developed on a printed circuit board of a semiconductor package according to an exemplary embodiment of the present invention, FIG. 2D is a view illustrating a state in which a copper post is plated on a printed circuit board of a semiconductor package according to an exemplary embodiment of the present invention, FIG. 2E is a view illustrating a state in which the dry film is delaminated from a printed circuit board of a semiconductor package according to an exemplary embodiment of the present invention, FIG. 2F is a view illustrating a state in which an etching process is performed on a printed circuit board of a semiconductor package according to an exemplary embodiment of the present invention, FIG. 3A is a view illustrating a state before an upper printed circuit board of a semiconductor package according to an exemplary embodiment of the present invention and a lower printed circuit board thereof are bonded, FIG. 3B is a view illustrating a state in which the upper printed circuit board of the semiconductor package according to an exemplary embodiment of the present invention and the lower printed circuit board thereof are bonded, FIG. 3C is a view illustrating a state in which a reflow is performed in a state in which the upper printed circuit board of the semiconductor package according to an exemplary embodiment of the present invention and the lower printed circuit board thereof are bonded, and FIG. 3D is a view illustrating a state in which the reflow is completed in a state in which the upper printed circuit board of the semiconductor package according to an exemplary embodiment of the present invention and the lower printed circuit board thereof are bonded.

As shown in FIG. 1, a semiconductor package 100 according to an exemplary embodiment of the present invention may include a lower package 10, an upper package 50 stacked on the lower package 10, and a bump 30 coupled to a solder ball 20 electrically connecting the lower package 10 and the upper package 50 to each other.

The lower package 10 may include a lower printed circuit board 12, a circuit pattern 14 formed on at least one surface of the lower printed circuit board 12, a solder resist layer applied so as to protect the circuit pattern 14, and a chip module 18 mounted so as to be connected to the circuit pattern 14.

The circuit pattern 14 formed on the lower printed circuit board 12 is configured by performing an etching process in a state in which a plating layer is stacked.

In addition, the solder resist layer 16 is applied onto an upper surface of the lower printed circuit board 12 to protect the circuit pattern 14.

In this case, although not shown in the drawings, the lower printed circuit board 12 may be provided with a via for connecting each layer when a plurality of printed circuit boards are stacked on a lower side of the lower printed circuit board 12.

In addition, the chip module 18 may be mounted on the lower printed circuit board 12. The chip module 18 may be disposed on a position at which the circuit pattern 14 is formed and may be electrically connected to the circuit pattern 14.

The upper package 50 stacked on the lower package 10 has circuit patterns 54 each formed on upper and bottom surfaces of the upper printed circuit board 52 and an electrical device (not shown) installed on the upper surface thereof by a mounting process such as a surface mounting technology (SMT).

That is, the circuit pattern 54 formed on the upper surface of the upper printed circuit board 52 is formed to mount the electrical device (not shown) and a solder resist layer 56 is formed to protect the circuit pattern. On the contrary, the circuit pattern 54 formed on the bottom surface of the upper printed circuit board 52 is formed so as to be electrically connected to the lower package 10.

Although not shown in the drawings, the electrical device may be molded by a molding material.

The upper package 50 and the lower package 10 configured as described above need to be configured so that an upper surface of the chip module 18 of the lower package 10 maintains a state in which it is spaced apart from the upper package 50 by a predetermined interval. That is, in order to prevent the chip module 18 and the upper package 50 from being connected to each other or prevent damage to an upper portion of the chip module 18 by the upper package 50 when external impact is applied, the upper package 50 and the lower package 10 need to maintain a predetermined interval.

To this end, a solder ball 20 and a bump 30 may be installed and coupled onto the lower package 10 and the upper package 50.

Although FIG. 1 shows a case in which the solder ball 20 is configured on the circuit pattern 54 of the upper package and the bump 30 is configured on the circuit pattern 14 of the lower package, on the contrary, the solder ball 20 may be configured on the lower package 10 and the bump 30 may be configured on the upper package 50.

Since the bump 30 coupled to the solder ball 20 has a receiving space 32 formed therein, it may receive a tip of the solder ball 20 therein when being coupled to the solder ball 20.

The entire shape of the bump 30 may be configured in various shapes such as a circular shape, a quadrangle shape, a polygonal shape, and the like and the shape of the receiving space 32 may also be designed and formed so as to have various shapes in order to stably receive the tip of the solder ball 20.

In addition, the bump 30 uses copper which is the same material as the circuit pattern 14 of the lower package, such that it may be integrated with the circuit pattern 14. In this case, the receiving space 32 of the bump 32 may be configured so as to have an inner diameter smaller than a diameter of the solder ball 20.

In addition, the bumps 30 may be configured so as to face and correspond to each other according to the positions and number of solder balls 20.

Therefore, when a reflow process is performed in a state in which the upper package 50 according to the exemplary embodiment of the present invention is coupled to the lower package 10, a portion of the solder ball 20 is melted and the melted solder ball is introduced into the receiving space 32 of the bump and cured, such that the bump 30 and the solder ball 20 are integrated.

In this case, the bump 30 may not have the receiving space formed therein and may be configured in a shape in which an upper surface thereof is depressed by a predetermined depth.

The depressed depth and an area of the bump 30 are formed by calculating a degree in which the solder ball 20 is received by a predetermined depth and is then partially melted in the reflow process to thereby be integrated with the bump 30.

As such, in the case in which the bump 30 and the solder 20 are configured so as to be integrated with each other in the reflow process, even though the center of the bump 30 and the center of the solder ball 20 do not accurately match during the coupling of the upper package 50 and the lower package 10 after separately manufacturing the upper package 50 and the lower package 10, the solder ball 20 and the bump 30 may be integrated, such that a time of a manufacturing process may be decreased and reliability of a product may also be secured.

Meanwhile, FIGS. 2A to 2F show processes of manufacturing a lower package among components of the semiconductor package according to an exemplary embodiment of the present invention.

Here, according to an exemplary embodiment of the present invention, a case in which one bump 30 is formed is shown as an example.

As shown, a lower package 10 having a circuit pattern 14 and a solder resist layer 16 applied onto a lower printed circuit board 12 is prepared.

Next, a seed layer 15 is formed on the circuit pattern 14. The seed layer 15 uses the same material as the circuit pattern 14.

In the case in which the seed layer 15 is formed on the circuit pattern 14, a plating dry film D is stacked on the solder resist layer 16.

In this case, the dry film D is stacked in consideration of a shape of the bump 30 so that the bump 30 may be integrally formed on the circuit pattern 14. That is, when the dry film D is stacked, in the case in which the bump 30 has a cylindrical shape and a structure having a receiving space formed therein, the dry film D is disposed at a position at which the receiving space will be formed and the dry film D is disposed at a position which is spaced apart from the disposed dry film D to the outside thereof by a predetermined interval.

In the case in which the dry film D is stacked as described above, copper is filled in a position at which the bump will be formed and the dry film D is then delaminated from the solder resist layer 16.

When the dry film D is removed, an etching process for removing the seed layer 15 is performed.

When the etching process is completed, a chip module 18 is mounted on the lower package 10.

In the case in which the lower package is completed through the processes as described above, the upper package 50 and the lower package 10 are assembled as shown in FIGS. 3A to 3D.

Here, the upper package 50 has a structure in which a circuit pattern 54, a solder resist layer 56, and an electrical device (not shown) are mounted on the upper printed circuit board 52. Since this structure corresponds to a general package process, a detail description thereof will be omitted.

As shown, after the upper package 50 and the lower package 10 are each manufactured, they are disposed so that the solder ball 20 and the bump 30 face each other.

In the case in which the displacement of the upper package 50 and the lower package 10 is completed, the upper package 50 is moved down and the lower package 10 is moved up until the solder ball 20 is closely adhered to the center of the bump 30.

After the solder ball 20 and the bump 30 are closed adhered to each other as described above, a reflow process is performed. When the reflow process is performed, a portion of the solder ball 20 is melted and introduced into the receiving space 32 of the bump.

In this case, it is noted that it needs to consider a time, a distance, and the like of a degree in which the solder ball 20 is not completely melted by the reflow process.

This is the reason that in the case in which the solder ball 20 is completely melted, the melted solder ball may exceed a filling amount of the receiving space 32 of the bump and a portion of the exceeded solder ball 20 may flow up to the circuit patterns 14 and 54 of the upper and lower packages or may be applied up to the circuit patterns 14 and 54 of the upper and lower packages.

In the case in which the upper package 50 and the lower package 10 are integrated with each other through the above mentioned processes, even though the center of the solder ball 20 and the center of the bump 30 do not accurately match, the solder ball 20 and the bump 30 may maintain a stable coupling state.

In addition, the total of height of the semiconductor package may be decreased and a predetermined gap between the chip module 18 and the upper printed circuit board 52 of the upper package may be formed by coupling the bump 30 to the solder ball 20 which is melted and introduced into the bump 30.

According to the exemplary embodiment of the present invention, the semiconductor package has the bump interposed between the upper and lower printed circuit boards having the electrical device mounted thereon, such that the solder ball may be melted and introduced into the bump when the reflow is performed to thereby maintain the stable coupling state of the upper and lower printed circuit boards, thereby making it possible to improve reliability and decrease the total of height of the package to thereby significantly improve product property.

Hereinabove, although the semiconductor package according to the exemplary embodiment of the present invention has been described, the present invention is not limited thereto, but may be variously modified and altered by those skilled in the art.

1. A semiconductor package comprising:
a lower package having a chip module mounted thereon so as to be connected to a circuit pattern;
an upper package stacked on the lower package and having an electrical device mounted thereon; and
a bump receiving a tip of a solder ball electrically connecting the lower package and the upper package and coupled to the solder ball.

2. The semiconductor package according to claim 1, wherein the bump is made of a copper material.

3. The semiconductor package according to claim 1, wherein the bump has a receiving space formed therein.

4. The semiconductor package according to claim 1, wherein the receiving space of the bump has an inner diameter smaller than a diameter of the solder ball.

5. The semiconductor package according to claim 1, wherein the bump has an upper surface configured so as to be depressed.

6. The semiconductor package according to claim 1, wherein the bump is configured so as to correspond to the positions and number of solder balls.

7. The semiconductor package according to claim 1, wherein the solder ball is partially melted and introduced into a receiving space of the bump when a reflow process is performed.

8. The semiconductor package according to claim 1, wherein the bump is formed in any one shape of a circular shape, a quadrangle shape, and a polygonal shape.

9. The semiconductor package according to claim 1, wherein the bump is configured integrally with the circuit pattern of the lower package.

10. The semiconductor package according to claim 3, wherein the receiving space of the bump has an inner diameter smaller than a diameter of the solder ball.
